(19) United States
(12) Patent Application Publication
(10) Pub. No.: US 2007/0284623 A1
(43) Pub. Date: Dec. 13, 2007

(54) Semiconductor device having vertical channel transistor

(76) Inventors: Sang-Jin Kim, Suwon-si (KR); Gi-sung Yeo, Seoul (KR); Joon-soo Park, Seongnam-si (KR); Han-ku Cho, Seongnam-si (KR); Sang-gyun Woo, Yongin-si (KR); Min-jong Hong, Seoul (KR)

Correspondence Address: LEE & MORSE, P.C., 3141 FAIRVIEW PARK DRIVE, SUITE 500, FALLS CHURCH, VA, 22042, US

(21) Appl. No.: 11/802,647

(22) Filed: May 24, 2007

(30) Foreign Application Priority Data
May 24, 2006 (KR) 10-2006-0046544

(51) Int. Cl. H01L 29/76; H01L 29/745

(52) U.S. Cl. 257/213

(57) ABSTRACT

A semiconductor device includes a substrate, and a plurality of active pillars arranged in a pattern of alternating even and odd rows and alternating even and odd columns, each active pillar extending from the substrate and including a channel portion, wherein the odd columns include active pillars spaced at a first pitch, the first pitch being determined in the column direction, the even columns include active pillars spaced at the first pitch, the even rows include active pillars spaced at a third pitch, the third pitch being determined in the row direction the odd rows include active pillars spaced at the third pitch, and active pillars in the even columns are offset by a second pitch from active pillars in the odd columns, the second pitch being determined in the column direction.

### BACKGROUND OF THE INVENTION

1. Field of the Invention

The present invention relates to a semiconductor device. More particularly, the present invention relates to a semiconductor device having a vertical channel transistor.

2. Description of the Related Art

Recent advances in the design of semiconductor devices employing planar transistors, where a gate electrode is formed on a semiconductor substrate and junction regions are formed at opposite sides of the gate electrode, have included efforts to decrease a channel length of the transistor in order to increase the integration density of the semiconductor devices. However, as the channel length is decreased, short channel effects such as Drain Induced Barrier Lowering (DIBL), hot carrier effects, punchthrough effects, etc., may occur. Various approaches have been proposed to prevent such short channel effects including, e.g., decreasing the depth of a junction region and forming a groove in a channel portion to increase a relative channel length. However, as the integration density of semiconductor memory devices, particularly Dynamic Random Access Memories (DRAMs), advances to the multi-gigabit range, such approaches may not be sufficient to prevent short channel effects.

In an effort to solve such problems, a vertical channel transistor, which has a channel disposed in the vertical direction with respect to the substrate, is being studied. When fabricating such a vertical channel transistor, an active pillar including a channel region may be formed by etching a substrate. However, since the active pillar generally has a small pitch and a tetragonally-shaped upper surface, photolithography becomes difficult. Accordingly, expensive photolithography equipment has to be employed.

### SUMMARY OF THE INVENTION

The present invention is therefore directed to a semiconductor device having a vertical channel transistor, which substantially overcomes one or more of the problems due to the limitations and disadvantages of the related art.

It is therefore a feature of an embodiment of the present invention to provide a semiconductor device having an arrangement of vertical channel transistors that exhibits an increased critical pitch of at least one feature.

It is therefore another feature of an embodiment of the present invention to provide a semiconductor device having an arrangement of vertical channel transistors wherein the vertical channel transistors have respective storage nodes disposed thereon, the storage nodes having a same arrangement as the vertical channel transistors.

It is therefore a further feature of an embodiment of the present invention to provide a semiconductor device having an arrangement of vertical channel transistors wherein the vertical channel transistors have respective storage nodes disposed thereon, the storage nodes having a different arrangement from the vertical channel transistors.

At least one of the above and other features and advantages of the present invention may be realized by providing a semiconductor device including a substrate and a plurality of active pillars arranged in a pattern of alternating even and odd rows and alternating even and odd columns, each active pillar extending from the substrate and including a channel portion, wherein the odd columns include active pillars spaced at a first pitch, the first pitch being determined in the column direction, the even columns include active pillars spaced at the first pitch, active pillars in the odd columns are spaced apart from active pillars in the even columns by a third pitch, the third pitch being determined in the row direction, and active pillars in the even columns are offset by a second pitch from active pillars in the odd columns, the second pitch being determined in the column direction.

The semiconductor device may further include at least one word line extending in the row direction, the word line electrically connecting active pillars in an odd row with active pillars in an adjacent even row. The word line may partially surround the channel portions of the active pillars to which it is connected. Adjacent word lines may be spaced at the first pitch.

The semiconductor device may further include at least one bit line within the substrate, the bit line extending in the column direction. The bit line may include an impurity region within the substrate, the impurity region extending in the column direction.

The semiconductor device may further include at least one bit line within the substrate and extending in the row direction, the bit line electrically connecting active pillars in an odd row with active pillars in an adjacent even row. Adjacent bit lines may be spaced at the first pitch. The semiconductor device may further include at least one word line extending in the column direction and electrically connected to a plurality of active pillars, the word line partially surrounding the channel portions of the active pillars to which it is connected. Adjacent word lines may be spaced at the third pitch.

The semiconductor device may further include storage node electrodes disposed on the active pillars and respectively connected to the active pillars. The storage node electrodes may be arranged in the same fashion as the arrangement of the active pillars. Storage node electrodes in the even columns may have centers that are substantially aligned with centers of storage node electrodes in the odd columns, the columns may include storage node electrodes spaced at the first pitch, and the rows may include storage node electrodes spaced at the third pitch.

The second pitch may be about ½ of the first pitch. The first pitch may be about ⅔ to about 3/2 of the third pitch.

At least one of the above and other features and advantages of the present invention may also be realized by providing a semiconductor device, including a substrate, a plurality of active pillars arranged in a pattern of alternating even and odd rows and alternating even and odd columns, each active pillar extending from the substrate and including a channel portion, wherein, the odd columns include active pillars spaced at a first pitch, the first pitch being determined in the column direction, the even columns include active pillars spaced at the first pitch, the even rows include active pillars spaced at a third pitch, the third pitch being determined in the row direction, the odd rows include active pillars spaced at the third pitch, and active pillars in the even columns have centers that are substantially aligned with centers of active pillars in the odd columns, and storage node electrodes disposed on and electrically connected to respective active pillars, wherein storage node electrodes in the odd columns are spaced at the first pitch, storage node electrodes in the even columns are spaced at the first pitch, and storage node electrodes in the even columns are offset by a second pitch from storage node electrodes in the odd columns.

The semiconductor device may further include word lines extending along rows of the active pillars, and bit lines extending along columns of the active pillars. The semiconductor device may further include word lines extending along columns of the active pillars, and bit lines extending along rows of the active pillars.

The second pitch may be about ½ of the first pitch. The first pitch may be about ⅔ to about 3/2 of the third pitch.

### BRIEF DESCRIPTION OF THE DRAWINGS

The above and other features and advantages of the present invention will become more apparent to those of ordinary skill in the art by describing in detail exemplary embodiments thereof with reference to the attached drawings, in which:

FIGS. 1A through 1G illustrate layouts of stages in a method of manufacturing a semiconductor device according to a first embodiment of the present invention;

FIGS. 2A through 2N illustrate sectional views, taken along a line X-X′ of a corresponding one of FIGS. 1A through 1G, of stages in the method of manufacturing the semiconductor device according to the first embodiment of the present invention;

FIGS. 3A through 3N illustrate sectional views, taken along a line Y-Y′ of a corresponding one of FIGS. 1A through 1G, of stages in the method of manufacturing the semiconductor device according to the first embodiment of the present invention;

FIGS. 4A through 4D illustrate layouts of stages in a method of manufacturing a semiconductor device according to a second embodiment of the present invention;

FIGS. 5A through 5D illustrate layouts of stages in a method of manufacturing a semiconductor device according to a third embodiment of the present invention;

FIGS. 6A through 6D illustrate layouts of stages in a method of manufacturing a semiconductor device according to a fourth embodiment of the present invention; and

FIG. 7 illustrates a layout of a conventional hard mask pattern.

### DETAILED DESCRIPTION OF THE INVENTION

Korean Patent Application No. 10-2006-0046544, filed on May 24, 2006, in the Korean Intellectual Property Office, and entitled: “Semiconductor Device Having Vertical Channel Transistor,” is incorporated by reference herein in its entirety.

The present invention will now be described more fully hereinafter with reference to the accompanying drawings, in which exemplary embodiments of the invention are illustrated. The invention may, however, be embodied in different forms and should not be construed as limited to the embodiments set forth herein. Rather, these embodiments are provided so that this disclosure will be thorough and complete, and will fully convey the scope of the invention to those skilled in the art.

In the figures, the dimensions of layers and regions may be exaggerated for clarity of illustration. In the following description, the terms “row” and “column” are used merely to describe various aspects of the drawing figures, and are not to be construed as limiting the scope of the present invention to a particular orientation or design. Further, “odd” and “even” rows may be interchanged, as may “odd” and “even” columns. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

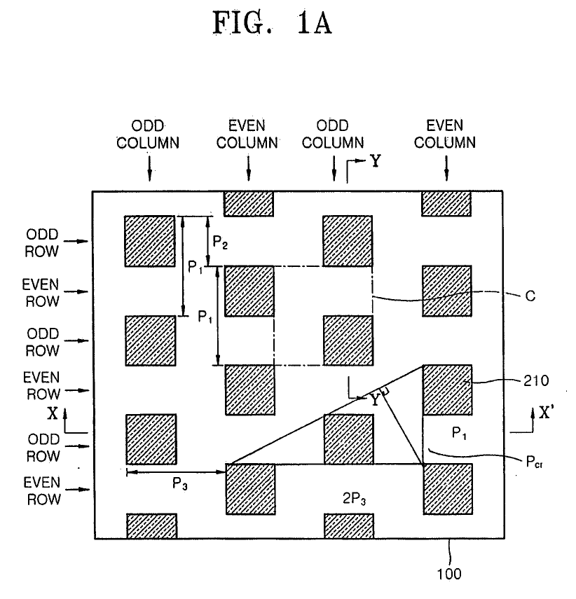

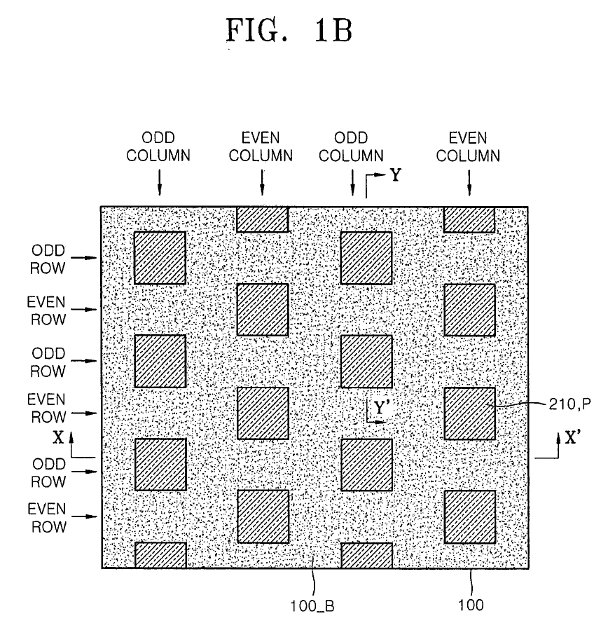

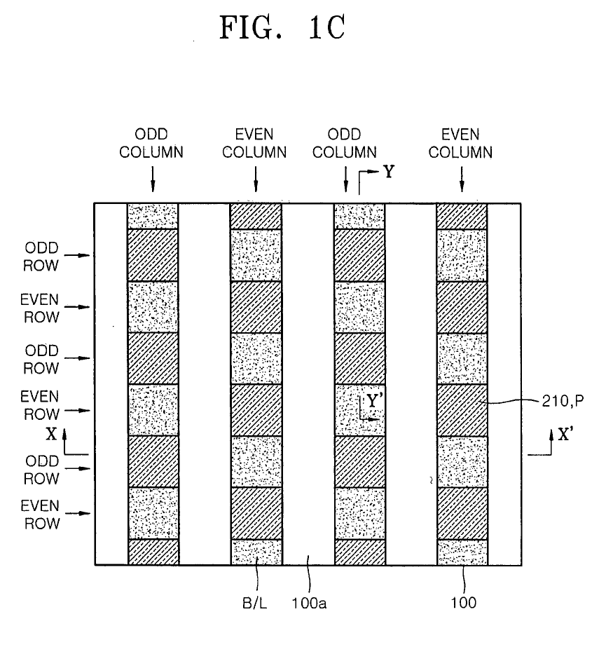

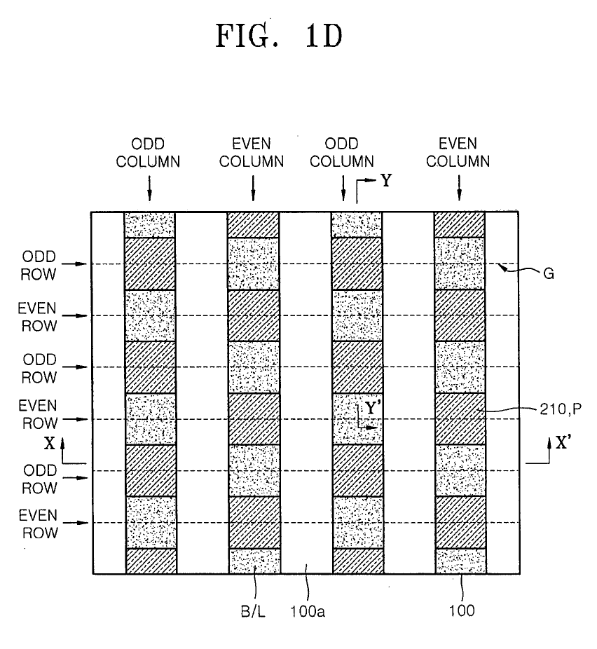

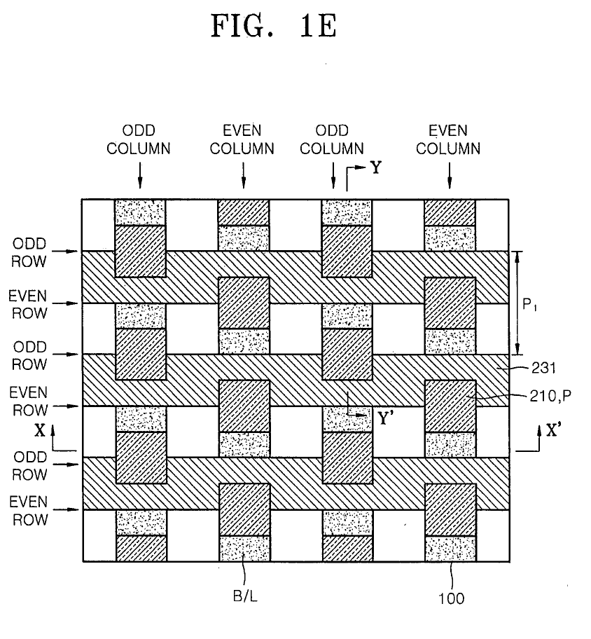

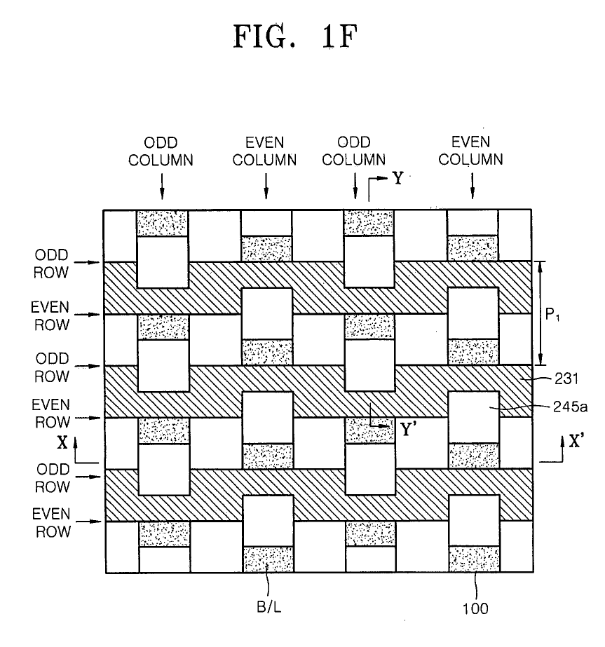

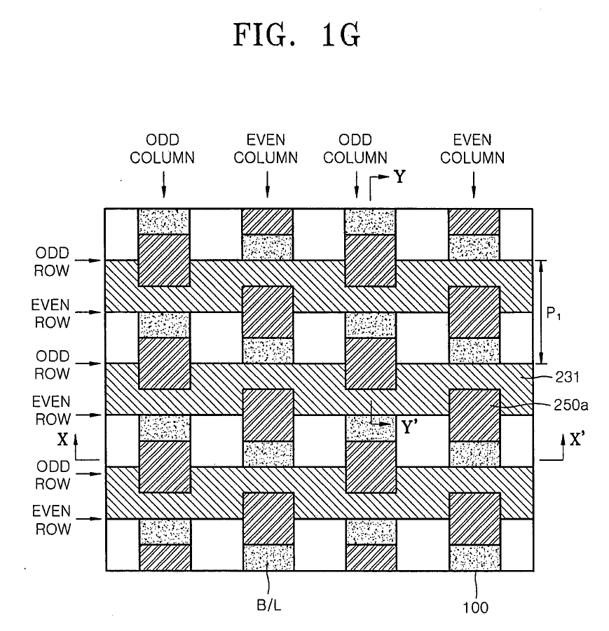

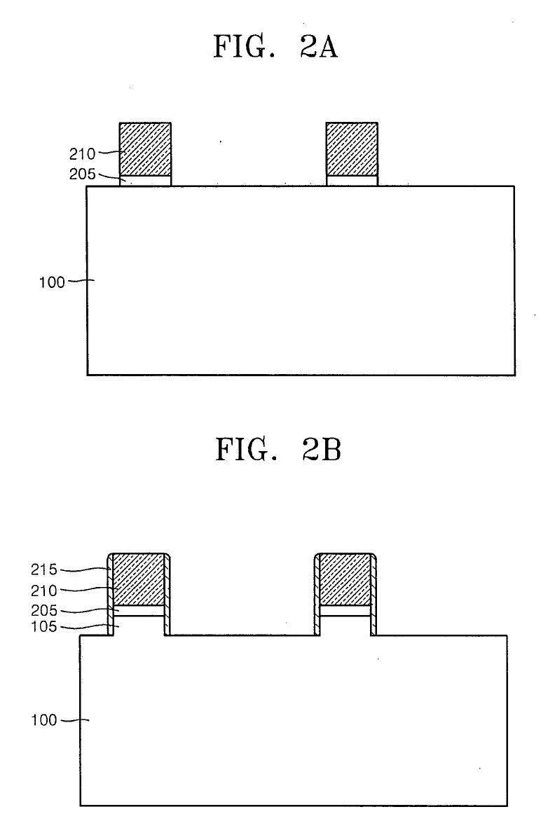

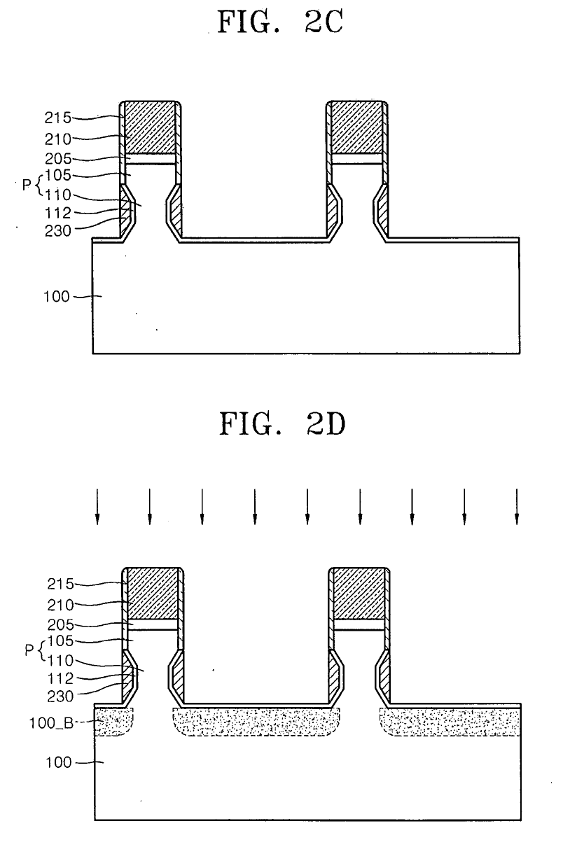

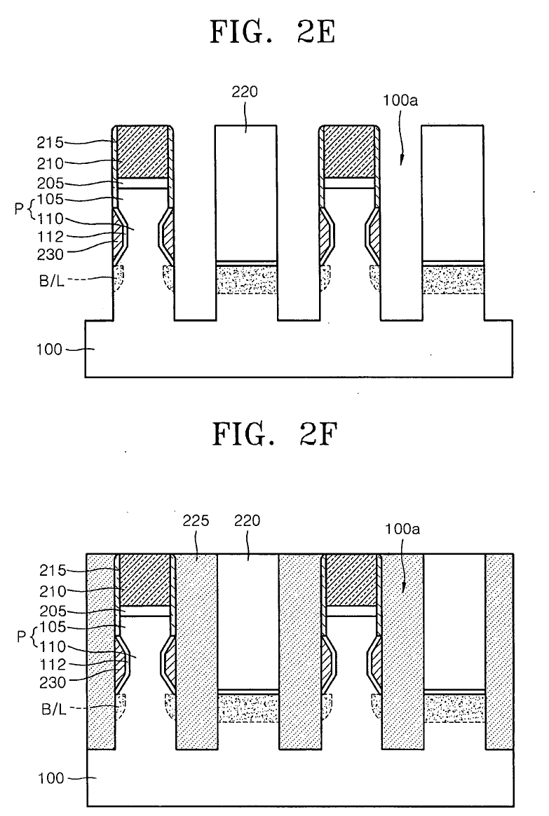

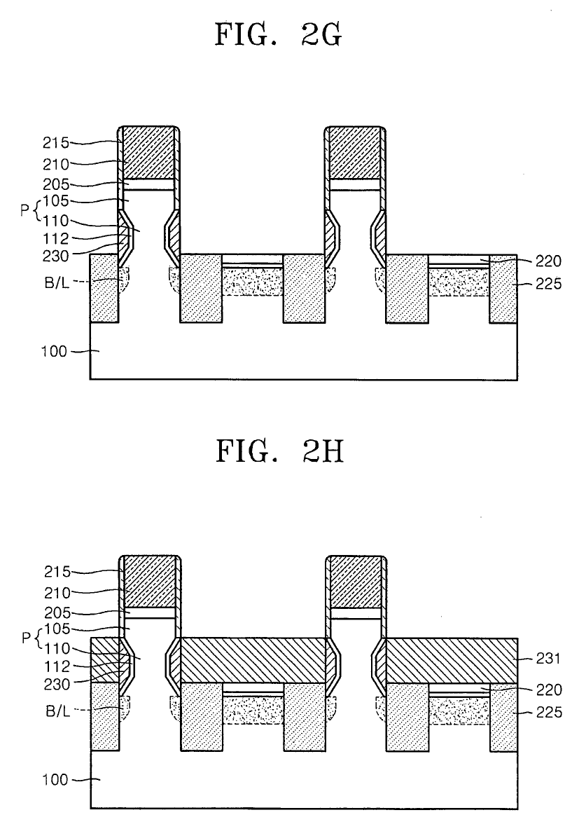

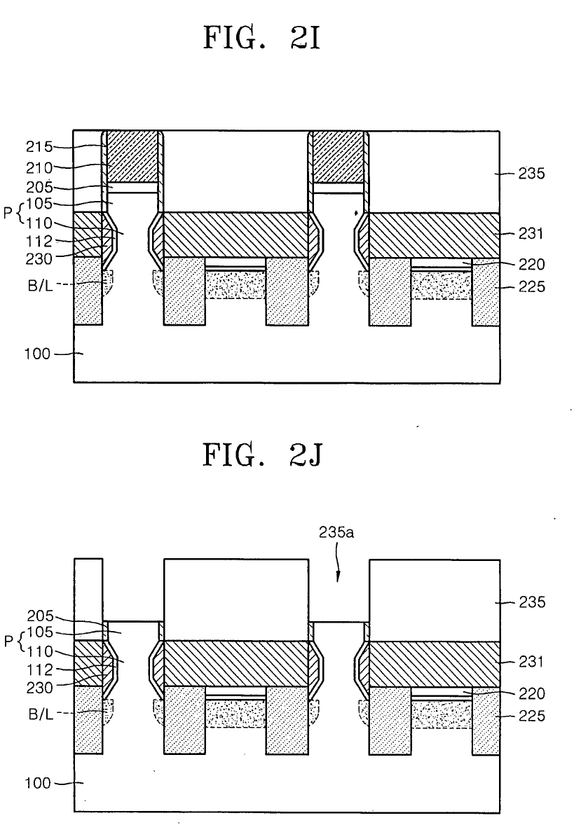

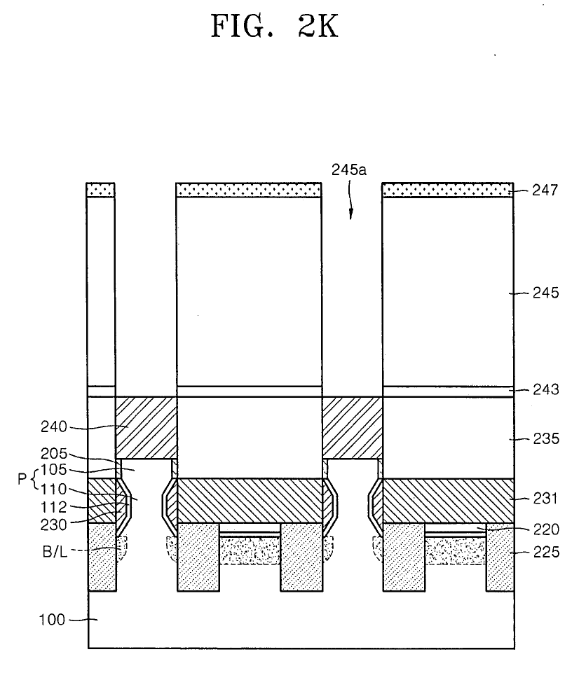

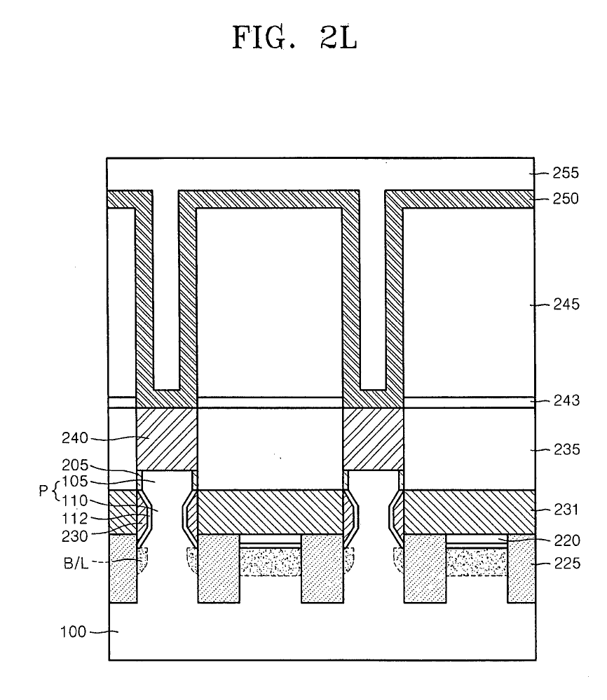

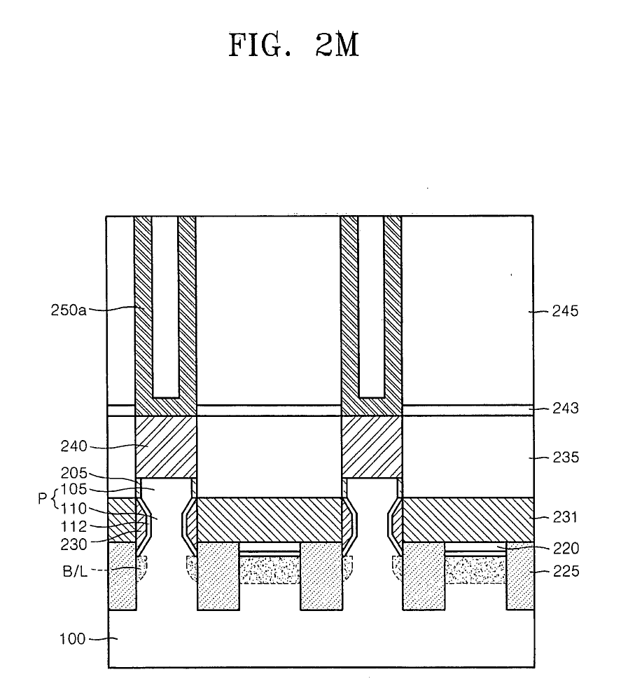

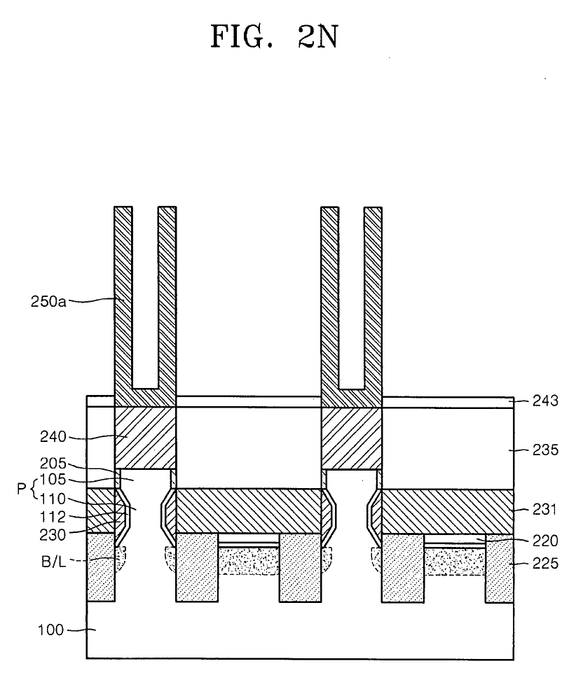

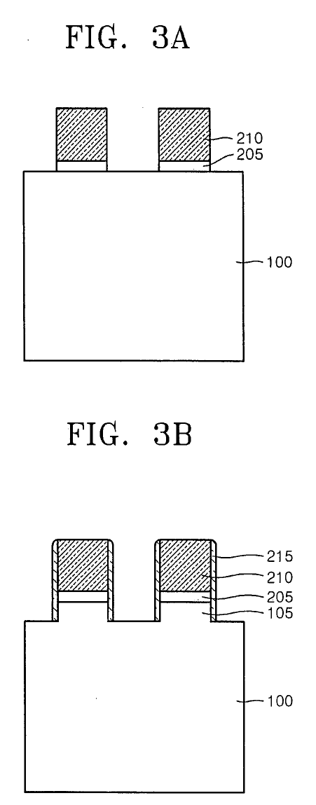

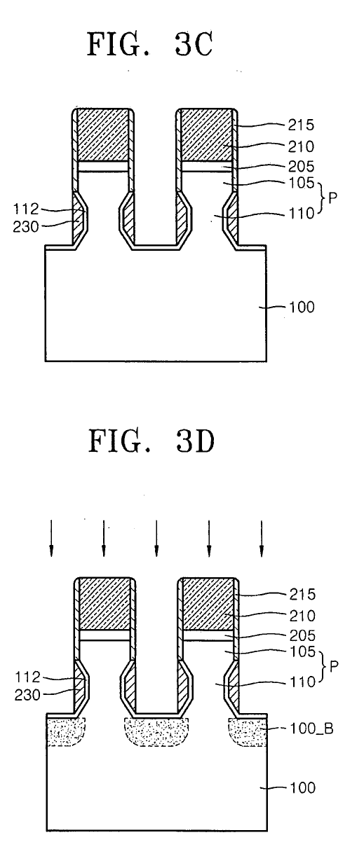

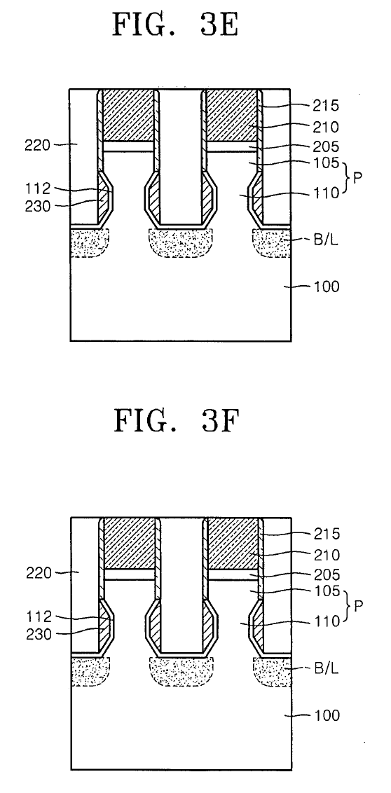

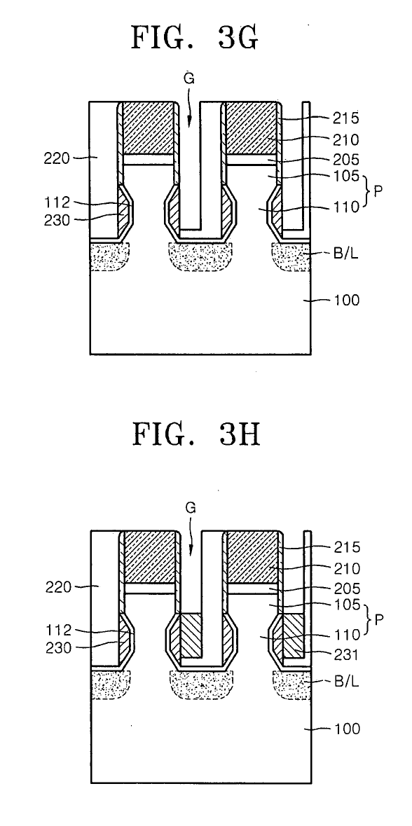

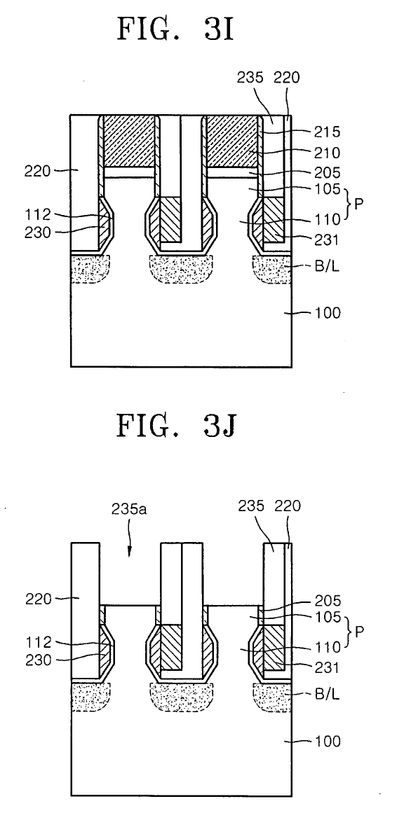

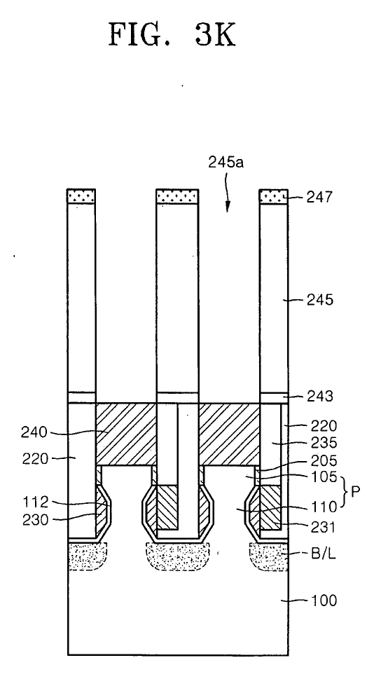

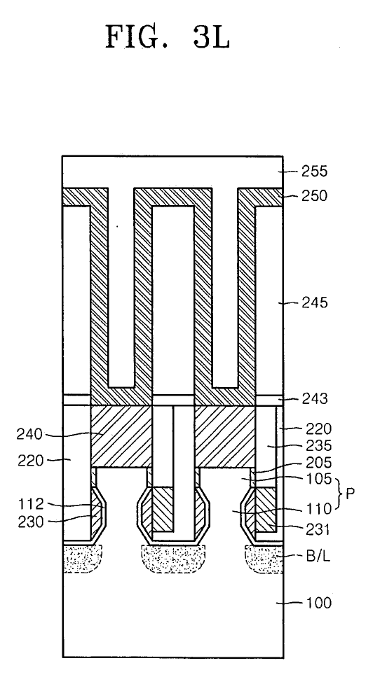

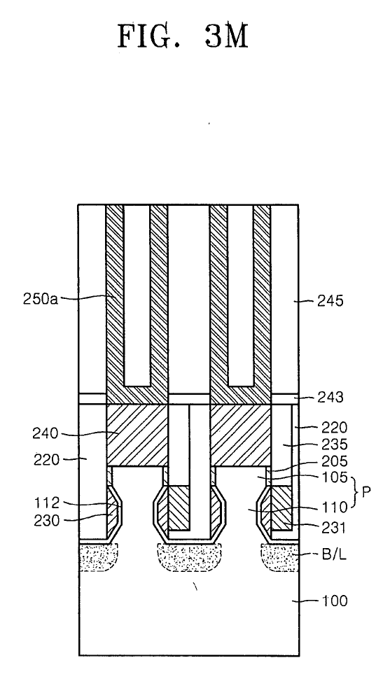

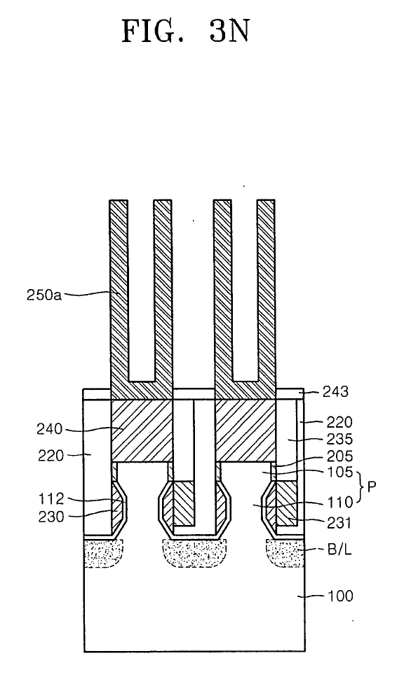

FIGS. 1A through 1G illustrate layouts of stages in a method of manufacturing a semiconductor device according to a first embodiment of the present invention, FIGS. 2A through 2N illustrate sectional views, taken along a line X-X′ of a corresponding one of FIGS. 1A through 1G, of stages in the method of manufacturing the semiconductor device according to the first embodiment of the present invention, and FIGS. 3A through 3N illustrate sectional views, taken along a line Y-Y′ of a corresponding one of FIGS. 1A through 1G, of stages in the method of manufacturing the semiconductor device according to the first embodiment of the present invention.

Referring to FIGS. 1A, 2A and 3A, a substrate 100 may be provided. The substrate 100 may be, e.g., a silicon mono-crystalline substrate, an epitaxial substrate having an epitaxial layer formed on a base substrate or a Silicon On Insulator (SOI) substrate, etc.

A pad oxide layer (not shown) may be formed on the substrate 100. The pad oxide layer may be formed by, e.g., thermal oxidation. A hard mask layer (not shown) may be stacked on the pad oxide layer. The hard mask layer may include a material having etching selectivity to the pad oxide layer and the substrate. In an implementation, the hard mask layer may include silicon nitride and/or silicon oxynitride. A photoresist layer (not shown) may be formed on the hard mask layer. The photoresist layer may be exposed using a first exposure mask (not shown) having a first exposure pattern, thereby forming a photoresist pattern (not shown). Thereafter, using the photoresist pattern as a mask, the hard mask layer and the pad oxide layer may be etched to form hard mask patterns 210 and underlying pad oxide layer patterns 205. The photoresist pattern may then be removed to expose the hard mask patterns 210.

The hard mask patterns 210 may be arranged in row and column directions, e.g., in alternating even and odd rows and even and odd columns. The hard mask patterns in each of the odd and even columns may be arranged at a first pitch P₁. The hard mask patterns 210 in the even columns may be shifted by a second pitch P₂ with respect to the hard mask patterns 210 in the odd columns. In an implementation, the second pitch P₂ may be about ½ of the first pitch P₁.

The odd columns and the even columns may be arranged at a third pitch P₃, the odd rows of the hard mask patterns 210 may include the hard mask patterns 210 in the odd columns, and the even rows of the hard mask patterns 210 may include the hard mask patterns 210 in the even columns. The hard mask patterns 210 within the odd rows may be arranged at a pitch that is about twice as large as the third pitch P₃, i.e., about 2P₃, and the hard mask patterns 210 within the even rows may also be arranged at a pitch that is about twice as large as the third pitch P₃, i.e., about 2P₃. The first pitch P₁ may be about ⅔ to about 3/2 times the third pitch P₃. In an implementation, the first pitch P₁ may be the same as the third pitch P₃.

An exposure mask for forming the hard mask patterns 210 may have first exposure patterns arranged in the same fashion as the hard mask patterns 210 illustrated in FIG. 1A. A critical pitch P_{cr} may be written as:

$$Pcr = \frac{{P}_{x} {P}_{y}}{\sqrt{{( {P}_{x} )}^{2} + {( {P}_{y} )}^{2}}} \qquad ( Equation 1 )$$

In Equation 1, Pₓ is a pitch in the x-axis direction and P_{y} is a pitch in the y-axis direction.

In an implementation of the first embodiment of the present invention, in Equation 1, Pₓ may be 2P₃, i.e., the pitch of the hard mask patterns 210 in respective rows, and P_{y} may be P₁, i.e., the pitch of the hard mask patterns 210 in respective columns. Also, the following relationships may be true Pₓ=2P₃=2P₁=4F and P_{y}=P₁=2F, where the third pitch P₃ is the same as the first pitch P₁, and the first pitch P₁ is twice the size of a minimum feature size F. Thus, according to Equation 1, the critical pitch P_{cr} may be

$$\frac{4}{\sqrt{5}} F .$$

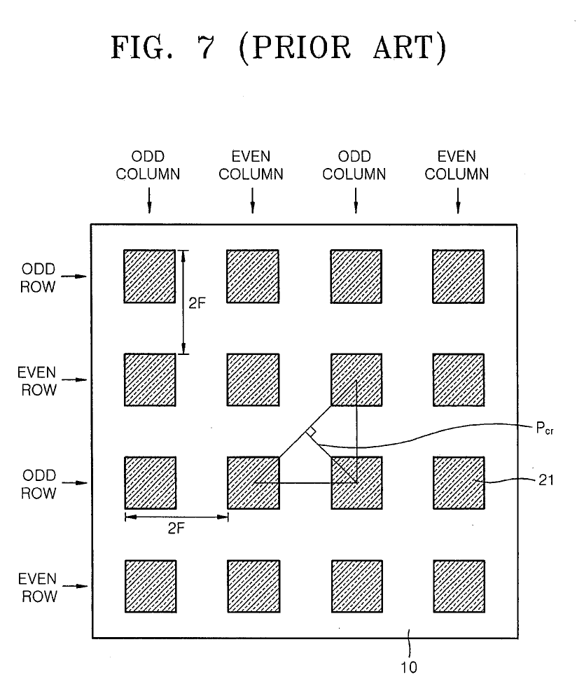

FIG. 7 illustrates a layout of a conventional hard mask pattern. Referring to FIG. 7, hard mask patterns 21 may be arranged in a checkerboard fashion, i.e., with centers substantially aligned in both row and column directions, such that they are disposed at the same pitch, i.e., 2F, within each of the odd columns, the even columns, the odd rows and the even rows. In this case, the critical pitch P_{cr} is \sqrt{2}F according to Equation 1, since Pₓ=2F and P_{y}=2F.

Consequently, the critical pitch P_{cr} of the device according to this embodiment of the present invention may be greater than P_{cr} of the conventional device shown in FIG. 7. Thus, embodiments of the present invention may be effective in relieving the critical pitch for forming the hard mask patterns. As a result, photolithographic processes for forming the hard mask patterns according to the present invention may be simplified, and in turn, productivity of the semiconductor device manufacturing process may be increased.

Referring again to FIG. 1A, a unit cell region C is illustrated. The length of one side of the unit cell region C may be the same as the pitch of the hard mask patterns 210 in the odd and even columns, i.e., the first pitch P₁. The length of a perpendicular side may be the same as the pitch between odd and even columns, i.e., the third pitch P₃. When the first pitch P₁ and the third pitch P₃ are the same, and the first pitch P₁ is twice of the minimum feature size F, a square feature size of the unit cell region C may be 4F².

Referring to FIGS. 1A, 2B and 3B, the substrate 100 may be etched to a predetermined depth using the hard mask patterns 210 as a mask, thereby forming first source/drain portions 105. The etching may be, e.g., anisotropic etching. In an implementation, a width of the first source/drain portions 105 may be substantially the same as a width of the hard mask patterns 210, and the first source/drain portions 105 may be arranged in the same fashion as the foregoing hard mask patterns 210.

A spacer material (not shown) may be stacked on the substrate 100 where the first source/drain portions 105 are formed and etched-back to form spacers 215 on sidewalls of the first source/drain portions 105. The spacers 215 may also be formed on sidewalls of the hard mask patterns 210. The spacer material may be a material having etching selectivity to the substrate 100, e.g., silicon nitride, silicon oxynitride, etc.

Referring to FIGS. 1A, 2C and 3C, channel portions 110 may be formed. In particular, using the hard mask patterns 210 and the spacers 215 as masks, the substrate 100 may be etched to a predetermined depth. The etching may be, e.g., anisotropic etching. Thus, a bar-shaped preliminary channel portion (not shown) may be formed of the substrate material, the preliminary channel portion extending integrally from a lower surface of the first source/drain portion 105. Then, using the hard mask patterns 210 and the spacers 215 as masks, the sidewalls of the preliminary channel portion may be etched by a predetermined width to yield the channel portion 110 having sides that are laterally recessed by the predetermined width, so that the vertical extent of the extending portion of the substrate 100 may be narrowed between the substrate 100 and the first source/drain portion 105. Thus, the width of the channel portion 110 may be decreased. The etching used to etch the sidewall of the channel portion 110 may be, e.g., isotropic etching.

The channel sections 110 and the first source/drain portions 105 disposed on the channel portions 110 may form active pillars P that upwardly extend from the substrate 100 and have respective channel portions 110. Since the channel portions 110 and the first source/drain portions 105 may be formed using the hard mask patterns 210 as the mask, the active pillars P may be arranged in the same fashion as the hard mask patterns 210.

Gate insulating layers 112 may be formed on surfaces of the recessed channel portions 110, and at the same time, the gate insulating layers 112 may be formed on the substrate 100 exposed between the active pillars P. The gate insulating layers 112 may be, e.g., a thermal oxide layer formed by thermal oxidation, a deposited oxide layer, etc. The gate insulating layer 112 may include, e.g., SiO₂, HfO₂, Ta₂O₅, Oxide/Nitride/Oxide (ONO), etc.

The channel portions 110 may be doped with channel impurities to form channel impurity regions (not shown) in the channel portions 110. The channel impurity region may suppress short channel effects of a transistor.

A gate conductive layer (not shown) may be stacked on the substrate 100. The gate conductive layer may include, e.g., n-type or p-type impurity-doped polysilicon or silicon germanium. The gate conductive layer may be anisotropically etched to form gate electrodes 230 that are filled into the lateral spaces in the channel portions 110. More specifically, the gate electrodes 230 may be surrounding gate electrodes that respectively surround the channel portions 110.

Where the channel portion 110 is laterally recessed by the predetermined width as described above, the recessed channel portion 110, i.e., the channel portion 110 with the narrow width, may be fully depleted when an operating voltage is supplied to the gate electrode 230 surrounding the channel portion 110. Consequently, the amount of current, i.e., the channel current, flowing through the channel portion 110 may be increased.

Referring to FIGS. 1B, 2D and 3D, the substrate 100 exposed between the active pillars P may be doped with a bit line impurity to form bit line impurity regions 100_B. The bit line impurity may be, e.g., an n-type impurity, e.g., phosphorous (P) or arsenic (As). The doping may be performed by, e.g., an ion implantation method. The doping with the bit line impurity may be done at a dose sufficient to decrease a sheet resistance.

Referring to FIGS. 1C, 2E and 3E, first interlayer insulating layers 220 may be stacked on the substrate 100. The first interlayer insulating layers 220 may be planarized until the hard mask patterns 210 are exposed. Thereafter, photoresist patterns (not shown) may be formed on the first interlayer insulating layers 220, and may be used as a mask to etch the first interlayer insulating layers 220, thereby exposing the substrate 100. The exposed substrate 100 may then be etched to a predetermined depth. Thus, device isolation trenches 100a extending in the column direction may be formed within the exposed substrate 100 between the columns of the active pillars P. The device isolation trenches 100a may penetrate through the bit line impurity regions 100_B that are shown in FIGS. 1B, 2D and 3D. Thus, buried bit lines B/L respectively extending from the columns of the active pillars P may be defined within the substrate 100. Regions of the buried bit lines B/L adjacent to the active pillars P may act as second source/drain portions. The buried bit lines B/L may be arranged at the third pitch P₃.

Referring to FIGS. 1C, 2F and 3F, buried insulating layers 225 that are formed in the device isolation trenches 100a may be formed on the substrate 100 having the device isolation trenches 100a. The device isolation trenches 100a may be filled with the buried insulating layers 225 to form the device isolation portions 100a. Subsequently, the buried insulating layers 225 may be planarized until the hard mask patterns 210 are exposed.

Referring to FIGS. 1D, 2G and 3G, photoresist patterns (not shown) may be formed on the first interlayer insulating layers 220 and on the buried insulating layers 225. Using the photoresist patterns as a mask, the first interlayer insulating layers 220 and the buried insulating layers 225 may be etched to form grooves G in the first interlayer insulating layers 220 and the buried insulating layers 225, the grooves G exposing the active pillars P.

The grooves G may be respectively located between the odd rows and the even rows of the active pillars P, thereby partially exposing the active pillars P disposed in the odd rows and the active pillars P disposed in the even rows. In more detail, when viewed from the plan view, the grooves G may be formed to partially traverse over the active pillars P disposed in the odd rows and the active pillars P disposed in the even rows. Also, the surrounding gate electrode 230 surrounding the channel portion 110 of the active pillar P may be exposed within the groove G. An insulating layer covering the bit line B/L may remain at the bottom of the groove G.

Referring to FIGS. 1E, 2H and 3H, conductive layers (not shown) may be formed in the grooves G for word lines. The word line conductive layers may include, e.g., a metal such as W, Co, Ni, Ti, etc.; a metal silicide such as tungsten silicide (WSiₓ), cobalt silicide (CoSiₓ), nickel silicide (NiSiₓ), titanium silicide (TiSiₓ); tungsten nitride/tungsten (WN/W), etc.

By etching-back the word line conductive layers, word lines 231 may be formed within the grooves G. Thus, the word lines 231 may be disposed between, i.e., in contact with, adjacent odd and even rows of the active pillars P. The word lines 231 may partially surround the channel portions 110 of the active pillars P disposed in the odd rows, as well as those of the channel portions 110 of the active pillars P disposed in the even rows. In particular, a word line 231 may be electrically connected to the surrounding gate electrodes 230 disposed in an odd row and the surrounding gate electrodes 230 disposed in an adjacent even row. In more detail, when viewed from the plan view, the word lines 231 may be disposed to partially traverse over the active pillars P in the odd rows and the active pillars P in the even rows. Therefore, because the word lines 231 are not cut by the active pillars P, but are physically connected, a linear resistance may be decreased. The word lines 231 may have a generally linear form. The word lines 231 may be arranged at the first pitch P₁.

Referring to FIGS. 1E, 2I and 3I, second interlayer insulating layers 235 may be formed in the grooves G so as to be stacked on the substrate 100 having the word lines 231 thereon. Then, the second interlayer insulating layers 235 may be planarized until the hard mask patterns 210 are exposed.

Referring to FIGS. 1E, 2J and 3J, the exposed hard mask patterns 210 and the underlying pad oxide layers 205 may be removed to expose the first source/drain portions 105, i.e., contact holes 235a that expose the first source/drain portions 105 may be formed in the second interlayer insulating layers 235. During this process, portions of the spacers 215, i.e., the portions formed on the sidewalls of the hard mask patterns 210 and the pad oxide layers 205, may be removed.

Subsequently, insulation spacer layers (not shown) may be stacked on the substrate 100 having the exposed first source/drain portions 105, and then etched-back to expose the surfaces of the upper source sections 110, thereby forming insulating spacers (not shown) along the sidewalls of the contact holes 235a. The insulation spacer layer may include a material that can be selectively etching with respect to the second interlayer insulating layer 235 and the first source/drain portion 105, e.g., silicon nitride, silicon oxynitride, etc.

Referring to FIGS. 1F, 2K and 3K, the exposed first source/drain portions 105 may be doped with an impurity to form source/drain regions (not shown). The source impurity may be a first type impurity. In an implementation, the source impurity may be an n-type impurity, e.g., P or As.

Thereafter, pad conductive layers may be filled into the contact holes 235a, and pad conductive layer material may then be planarized until surfaces of the second interlayer insulating layers 235 are exposed, thereby forming contact pads 240 connected to the first source/drain portions 105 within the contact holes 235a.

Etch stop layers 243 and mold insulating layers 245 may be sequentially stacked on the substrate 100 on which the contact pads 240 are formed. A height of a storage node electrode, described below, may be determined based on a thickness of the mold insulating layer 245. The mold insulating layer 245 may include, e.g., silicon oxide. The etch stop layer 243 may have etching selectivity with respect to the mold insulating layer 245 and may shield the underlying interlayer insulating layers 220 and 235. In an implementation, the mold insulating layer 245 may include silicon oxide and the etch stop layer 243 may include, e.g., silicon nitride or silicon oxynitride.

After forming photoresist layers (not shown) on the mold insulating layers 245, the photoresist layers may be exposed using second exposure masks (not shown) having second exposure patterns to form a photoresist pattern 247 on the mold insulating layer 245. Using the photoresist pattern 247 as a mask, the mold insulating layers 245 and the etch stop layers 243 may be etched to define contact hole-shaped electrode regions 245a within the mold insulating layers 245 and the etch stop layers 243, such that the electrode regions 245a may expose the contact pads 240. The etching of the mold insulating layer 245 and the etch stop layer 243 may be dry etching, e.g., anisotropic etching.

The electrode regions 245a may be substantially aligned with the active pillars P, and thus the electrode regions 245a may have the same arrangement as the active pillars P, i.e., the same arrangement as the hard mask patterns 210 of FIG. 1A. Therefore, a critical pitch during photolithography for forming the electrode regions 245a may be the same as the critical pitch during photolithography for forming the hard mask patterns 210 of FIG. 1A. Accordingly, photolithography for forming the electrode regions 245a may be simplified, which in turn may increase productivity of the semiconductor device manufacturing process.

Referring to FIGS. 1F, 2L and 3L, a storage conductive layer 250 of a predetermined thickness may be stacked along the inner surfaces of the electrode regions 245a and the upper surfaces of the mold insulating layers 245. The storage conductive layer 250 may include, e.g., doped polysilicon, Ti, TiN, TaN, W, WN, Ru, Pt, Ir, multiple layers and combinations of these materials, etc.

A buffer insulating layer 255 may be stacked on the storage conductive layer 250. The buffer insulating layer 255 may be formed so as to fill the electrode regions 245a. The buffer insulating layer 255 may be formed using, e.g., atomic layer deposition. The buffer insulating layer 255 may have a similar etching selectivity with respect to the mold insulating layer 245 and may include, e.g., silicon oxide.

Referring to FIGS. 1G, 2M and 3M, the buffer insulating layer 255 and the storage conductive layer 250 may be partially removed, e.g., through a planarization-etch process, until the surface of the mold insulating layer 245 is exposed. The planarization etching may be, e.g., chemical mechanical polishing, etch-back, etc. As a result of the planarization, cylindrically-shaped storage node electrodes 250a may be formed that cover bottom surfaces and sidewalls of the electrode regions 245a and are disposed on the active pillars P so as to be respectively connected to the active pillars P.

Referring to FIGS. 1G, 2N and 3N, the buffer insulating layer 255 and the mold insulating layer 245 within the electrode regions 245 may be etched, e.g., using wet etchant. The wet etchant may be, e.g., diluted HF solution, Buffered Oxide Etch (BOE) solution, etc. Thus, inner and outer surfaces of each cylindrically-shaped storage node electrode 250a may be exposed, and the etch stop layer 243 may be exposed around the storage node electrodes 250a. This may complete the formation of the storage node electrodes 250a on the substrate 100.

The storage node electrodes 250a may be connected to the contact pads 240. The storage node electrodes 250a may include, e.g., doped polysilicon, Ti, TiN, TaN, W, WN, Ru, Pt, Ir, multiple layers and combinations of these materials, etc. In an implementation (not shown), the contact pads 240 may be omitted such that the storage node electrodes 250a are directly connected to the first source/drain portions 105. The arrangement of the storage node electrodes 250a may correspond to that of the electrode regions 245a. Thus, the storage node electrodes 250a may be arranged in a similar fashion to the active pillars P.

As described above, a one cylinder storage (OCS) type node electrode is used as an example of the storage node electrodes 250a. However, it will be appreciated that the present invention is not limited to an OCS type node electrode. For example the storage electrode may be implemented as a plate type storage node electrode, a pillar-type storage node electrode with the active pillar P extending to an upper portion, etc.

A dielectric film (not shown) may be stacked on surfaces of the storage node electrodes 250a, and plate electrodes (not shown) surrounding the upper storage electrodes 250a may be formed on the dielectric film. The storage node electrodes 250a, the dielectric film and the plate electrodes may thus form a capacitor.

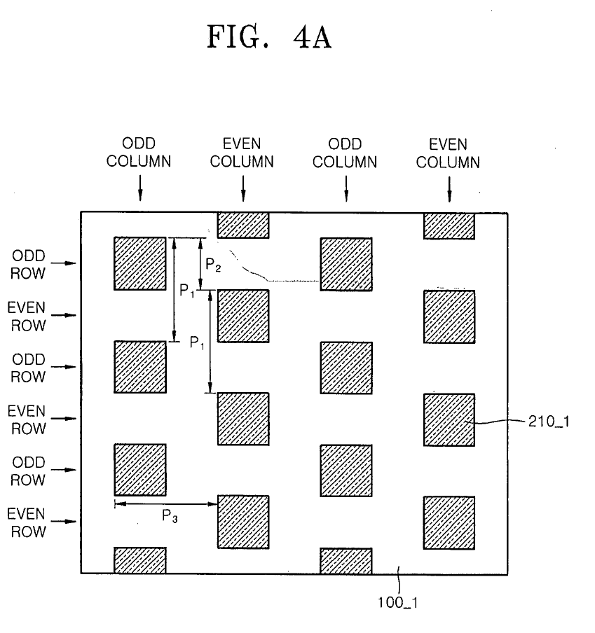

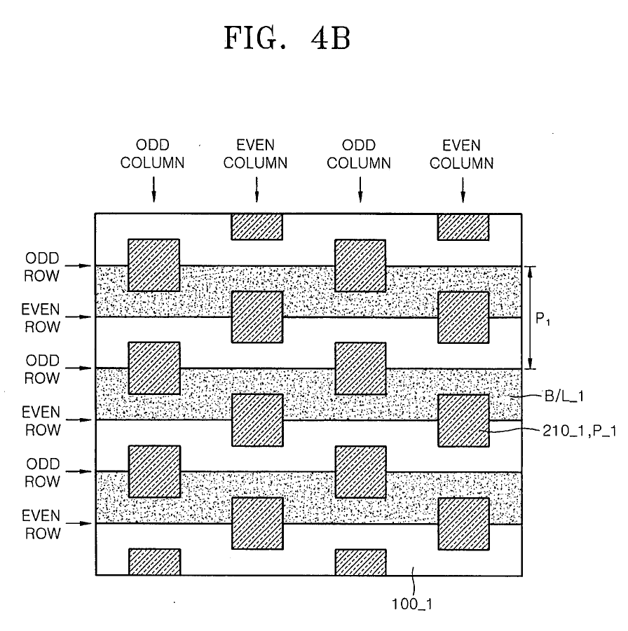

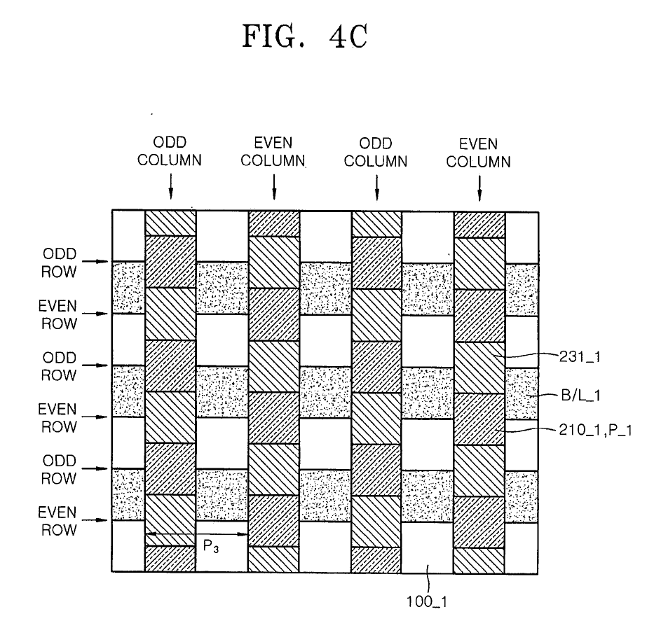

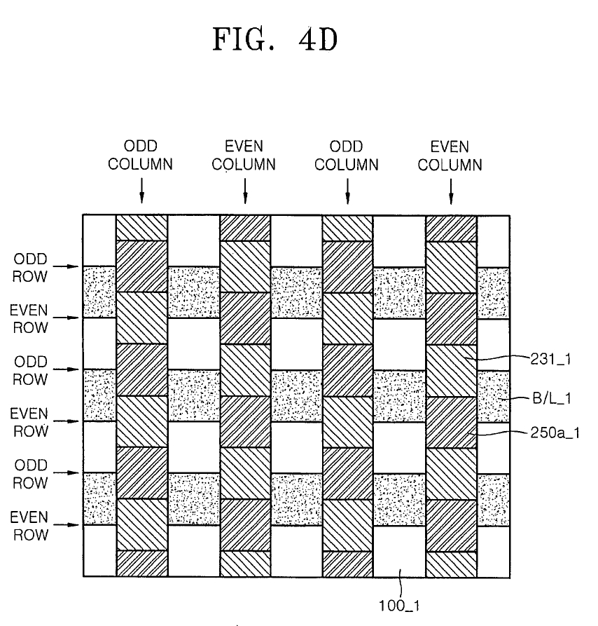

FIGS. 4A through 4D illustrate layouts of stages in a method of manufacturing a semiconductor device according to a second embodiment of the present invention. This embodiment may be similar to the first embodiment described above except for the arrangement of the bit lines and the word lines.

Referring to FIG. 4A, hard mask patterns 210_1 may be formed on a substrate 100_1. The hard mask patterns 210_1 may be arranged in the same fashion as the hard mask patterns 210 described with reference to FIG. 1A.

Referring to FIG. 4B, the substrate 100_1 may be etched using the hard mask patterns 210_1, thereby forming active pillars P_1 that respectively have channel portions under the hard mask patterns 210_1. Bit lines B/L_1 may be formed within the substrate 100_1 between odd rows and even rows of the active pillars P_1, and may be connected to the active pillars P_1 in the odd rows and the active pillars P_1 in the even rows. The bit lines B/L_1 are not disconnected by the active pillars P_1 but are physically connected, thereby decreasing the linear resistance. The bit lines B/L_1 may be arranged at the first pitch P₁.

Referring to FIG. 4C, word lines 231_1 respectively extending along the columns of the active pillars P_1 may be further disposed on the substrate 100_1. When surrounding gate electrodes, which respectively surrounding the channel portions of the active pillars P_1, are disposed along outer peripheries of the active pillars P_1, respective word lines 231_1 may be electrically connected to the surrounding gate electrodes disposed in respective columns. The word lines 231_1 may be arranged at the third pitch P₃.

Referring to FIG. 4D, storage node electrodes 250a_1 may be respectively connected to the active pillars P_1 and may be disposed on the active pillars P_1. The storage node electrodes 250a_1 may be arranged in the same fashion as the active pillars P_1.

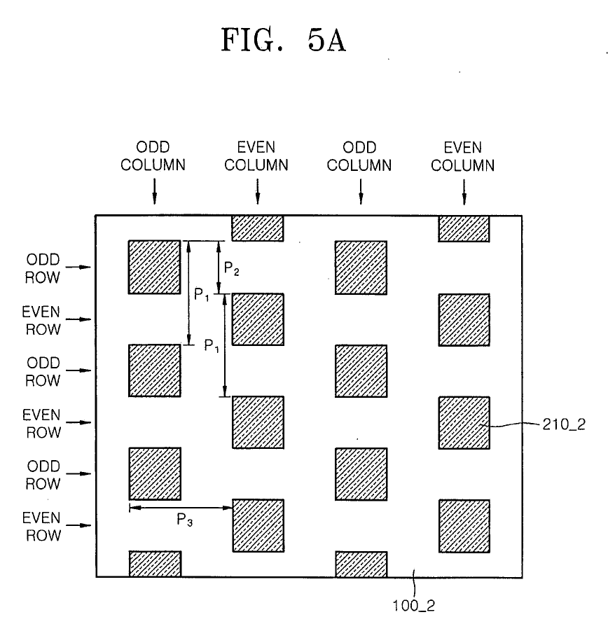

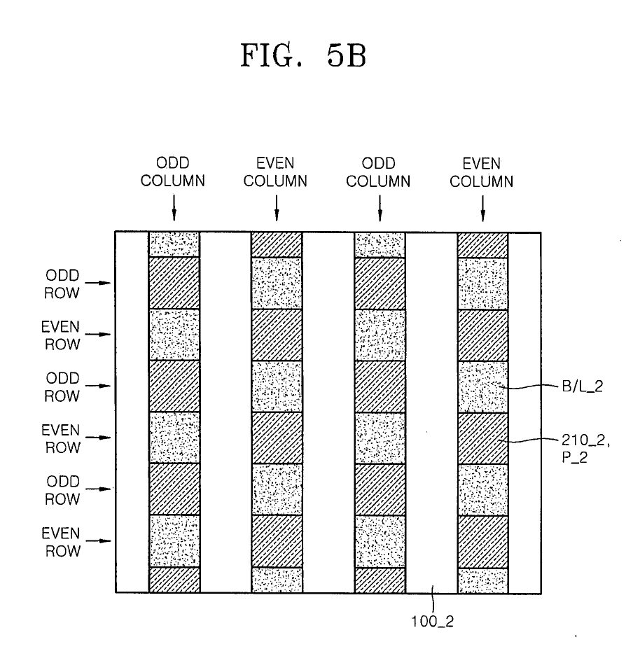

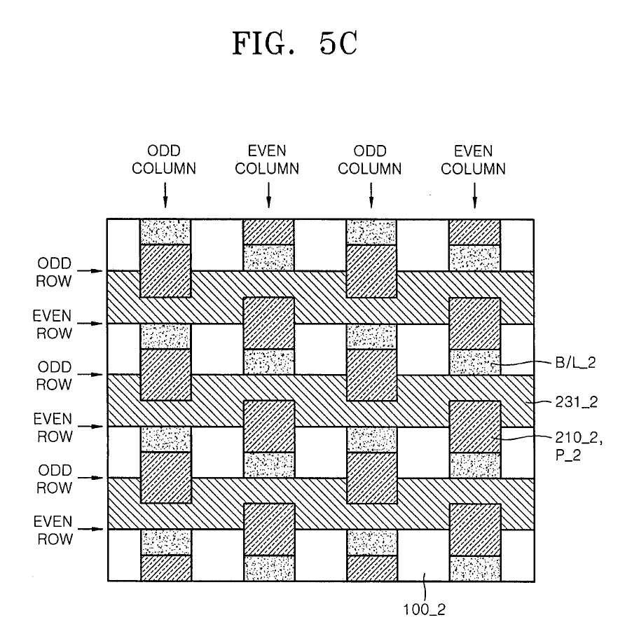

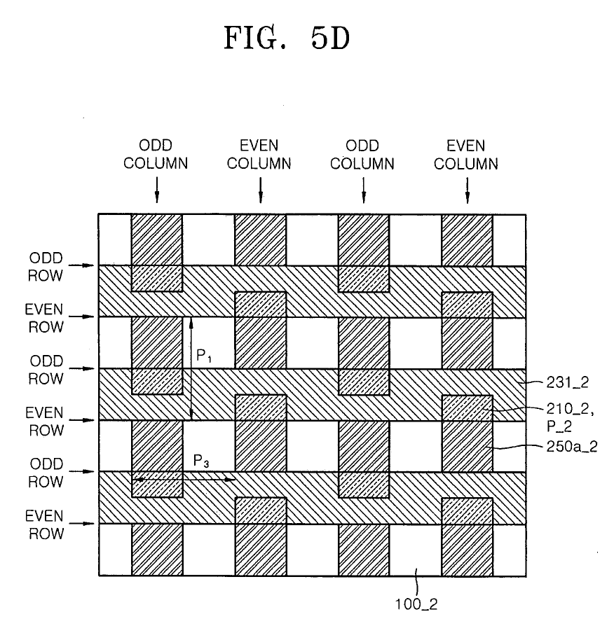

FIGS. 5A through 5D illustrate layouts of stages in a method of manufacturing a semiconductor device according to a third embodiment of the present invention. This embodiment may be similar to the first embodiment described above except for the arrangement of the storage node electrodes.

Referring to FIGS. 5A through 5D, hard mask patterns 210_2, active pillars P_2, bit lines B/L_2 and word lines 231_2 may be respectively arranged in similar fashion to the hard mask patterns 210, the active pillars P, the bit lines B/L and the word lines 231 described above. However, storage node electrodes 250a_2 may be arranged in a checkerboard fashion, unlike the storage node electrode 250a of FIG. 1G described with reference to FIG. 1G. That is, the storage node electrodes 250a_2 in an odd column may have centers that are substantially aligned with centers of storage node electrodes 250a_2 in an even column.

In more detail, the storage node electrodes 250a_2 may be arranged at the first pitch P₁ within all columns, and arranged at the third pitch P₃ within all rows. The first pitch P₁ may be about ⅔ to about 3/2 times the size of the third pitch P₃. In an implementation, the first pitch P₁ may be the same as the third pitch P₃. The storage node electrodes 250a_2 in even columns may not be offset with respect to storage node electrodes 250a_2 in odd columns, i.e., they may not be shifted by a predetermined pitch with respect to those in the odd columns. When viewed from a plan view, the storage node electrodes 250a_2 may overlap with upper portions of the active pillars P_2 disposed in the odd rows, and may overlap with lower portions of the active pillars P_2 disposed in the even rows.

In manufacturing the semiconductor device according to this embodiment, the critical pitch of photolithography for forming the storage node electrodes 250a_2 may be unchanged, whereas the critical pitch of photolithography for forming the hard mask patterns 210_2 may be relieved.

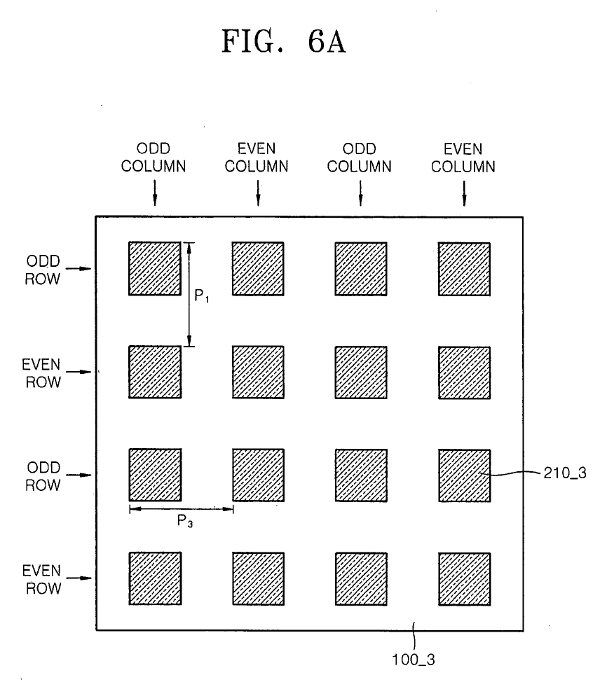

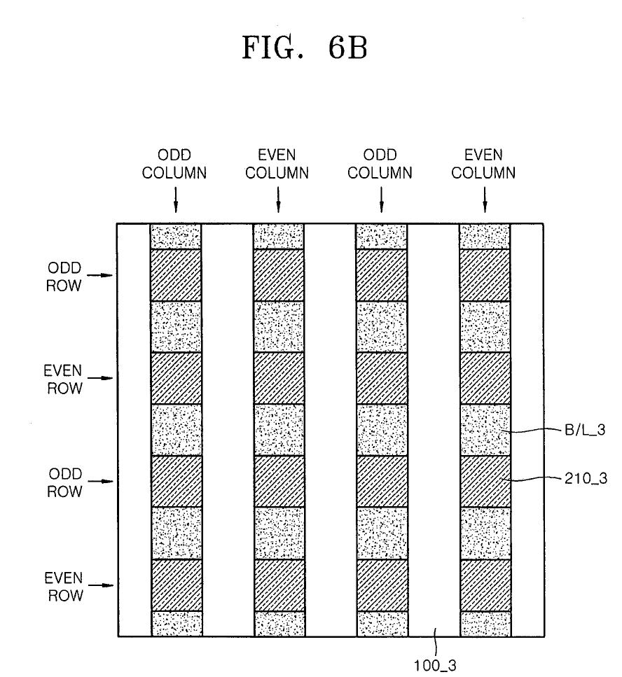

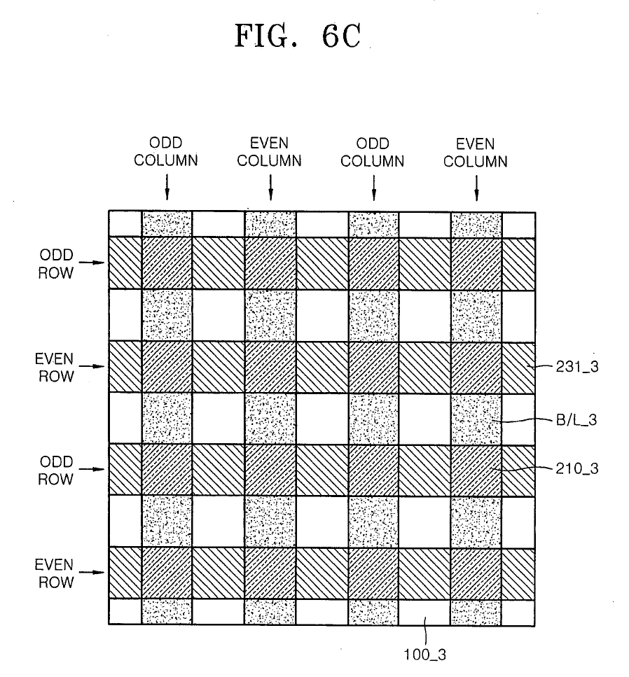

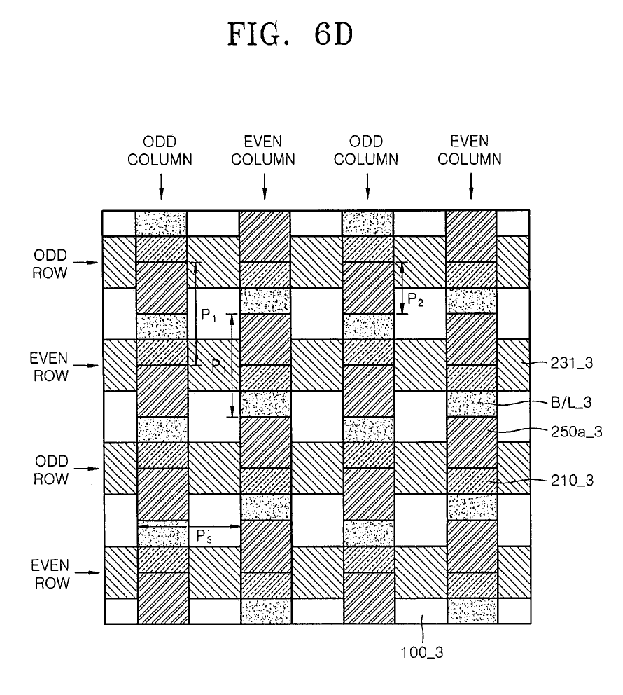

FIGS. 6A through 6D illustrate layouts of stages in a method of manufacturing a semiconductor device according to a fourth embodiment of the present invention. This embodiment may be similar to the first embodiment described above except for the arrangement of the hard mask patterns and the active pillars.

Referring to FIG. 6A, hard mask patterns 210_3 may be arranged in a checkerboard fashion. More specifically, the hard mask patterns 210_3 may be arranged at the first pitch P₁ within all columns and may be arranged at the third pitch P₃ within all rows. The first pitch P₁ may be about ⅔ to about 3/2 times the third pitch P₃. In an implementation, the first pitch P₁ may be the same as the third pitch P₃. The hard mask patterns 210_3 in even columns may be substantially centered with the hard mask patterns 210_3 in odd columns, such that the hard mask patterns 210_3 in the even columns are not shifted by a predetermined pitch with respect those in the odd columns. Using the hard mask patterns 210_3 as a mask, a substrate 100_3 may be etched to form active pillars P_3 respectively having channel portions under the hard mask patterns 210_3. The active pillars P_3 and the hard mask patterns 210_3 may be identically arranged.

Referring to FIG. 6B, bit lines B/L_3 may respectively extend along the columns of the active pillars P_3 and may be disposed within the substrate 100_3.

Referring to FIG. 6C, word lines 231_3 may respectively extend along the rows of the active pillars P_3 and may be disposed on the substrate 100_3. When surrounding gate electrodes, which may respectively surround the channel portions of the active pillars P_3, are disposed on the outer peripheries of the active pillars P_3, respective word lines 231_3 may be electrically connected to the surrounding gate electrodes disposed in respective rows. In another implementation (not shown), bit lines may extend along the rows of the active pillars P_3 and word lines may extend along the columns of the active pillars P_3.

Referring to FIG. 6D, storage node electrodes 250a_3 that are respectively connected to the active pillars P_3 may be disposed on the active pillars P_3. The storage node electrodes 250a_3 may be arranged in the same fashion as the storage node electrodes 250a described above with reference to FIG. 1G. The storage node electrodes 250a_3 may be arranged at the first pitch P₁ within the odd columns and the even columns. The storage node electrodes 250a_3 disposed in the even columns may be shifted by the second pitch P₂ with respect to the storage node electrodes 250a_3 disposed in the odd columns. Additionally, adjacent odd and even columns may be spaced at the third pitch P₃. The second pitch P₂ may be about ½ of the first pitch P₁, and the first pitch P₁ may be about ⅔ to about 3/2 times the third pitch P₃. When viewed from the plan view, the storage node electrodes 250a_3 may overlap with lower portions of the active pillars P_3 disposed in the odd columns, and overlap with upper portions of the active pillars P_3 disposed in the even columns.

When manufacturing the semiconductor device according to this embodiment of the present invention, the critical pitch of photolithography for forming the hard mask patterns 210_3 may be unchanged, whereas the critical pitch of photolithography for forming the storage node electrodes 250a_3 may be relieved.

When forming a vertical channel transistor according to the present invention as described above, active pillars and/or storage node electrodes may be arranged at a first pitch within odd columns or even columns, and the active pillars and/or storage node electrodes arranged within the even columns may be shifted by a second pitch with respect to the active pillars and/or storage node electrodes arranged within the odd columns. Thus, a critical pitch of photolithography for forming the active pillars and/or storage node electrodes may be relieved, which may simplify photolithography and increase productivity.

Exemplary embodiments of the present invention have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A semiconductor device, comprising:
a substrate; and
a plurality of active pillars arranged in a pattern of alternating even and odd rows and alternating even and odd columns, each active pillar extending from the substrate and including a channel portion, wherein:
the odd columns include active pillars spaced at a first pitch, the first pitch being determined in the column direction,
the even columns include active pillars spaced at the first pitch,
active pillars in the odd columns are spaced apart from active pillars in the even columns by a third pitch, the third pitch being determined in the row direction, and
active pillars in the even columns are offset by a second pitch from active pillars in the odd columns, the second pitch being determined in the column direction.

2. The semiconductor device as claimed in claim 1, further comprising at least one word line extending in the row direction, the word line electrically connecting active pillars in an odd row with active pillars in an adjacent even row.

3. The semiconductor device as claimed in claim 2, wherein the word line partially surrounds the channel portions of the active pillars to which it is connected.

4. The semiconductor device as claimed in claim 2, wherein adjacent word lines are spaced at the first pitch.

5. The semiconductor device as claimed in claim 1, further comprising at least one bit line within the substrate, the bit line extending in the column direction.

6. The semiconductor device as claimed in claim 5, wherein the bit line includes an impurity region within the substrate, the impurity region extending in the column direction.

7. The semiconductor device as claimed in claim 1, further comprising at least one bit line within the substrate and extending in the row direction, the bit line electrically connecting active pillars in an odd row with active pillars in an adjacent even row.

8. The semiconductor device as claimed in claim 7, wherein adjacent bit lines are spaced at the first pitch.

9. The semiconductor device as claimed in claim 7, further comprising at least one word line extending in the column direction and electrically connected to a plurality of active pillars, the word line partially surrounding the channel portions of the active pillars to which it is connected.

10. The semiconductor device as claimed in claim 9, wherein adjacent word lines are spaced at the third pitch.

11. The semiconductor device as claimed in claim 1, further comprising storage node electrodes disposed on the active pillars and respectively connected to the active pillars.

12. The semiconductor device as claimed in claim 11, wherein the storage node electrodes are arranged in the same fashion as the arrangement of the active pillars.

13. The semiconductor device as claimed in claim 11, wherein storage node electrodes in the even columns have centers that are substantially aligned with centers of storage node electrodes in the odd columns,
the columns include storage node electrodes spaced at the first pitch, and
the rows include storage node electrodes spaced at the third pitch.

14. The semiconductor device as claimed in claim 1, wherein the second pitch is about ½ of the first pitch.

15. The semiconductor device as claimed in claim 1, wherein the first pitch is about ⅔ to about 3/2 of the third pitch.

16. A semiconductor device, comprising:
a substrate;
a plurality of active pillars arranged in a pattern of alternating even and odd rows and alternating even and odd columns, each active pillar extending from the substrate and including a channel portion, wherein:
the odd columns include active pillars spaced at a first pitch, the first pitch being determined in the column direction,
the even columns include active pillars spaced at the first pitch,
the even rows include active pillars spaced at a third pitch, the third pitch being determined in the row direction,
the odd rows include active pillars spaced at the third pitch, and
active pillars in the even columns have centers that are substantially aligned with centers of active pillars in the odd columns; and
storage node electrodes disposed on and electrically connected to respective active pillars, wherein:
storage node electrodes in the odd columns are spaced at the first pitch,
storage node electrodes in the even columns are spaced at the first pitch, and
storage node electrodes in the even columns are offset by a second pitch from storage node electrodes in the odd columns.

17. The semiconductor device as claimed in claim 16, further comprising word lines extending along rows of the active pillars, and bit lines extending along columns of the active pillars.

18. The semiconductor device as claimed in claim 16, further comprising word lines extending along columns of the active pillars, and bit lines extending along rows of the active pillars.

19. The semiconductor device as claimed in claim 16, wherein the second pitch is about ½ of the first pitch.

20. The semiconductor device as claimed in claim 16, wherein the first pitch is about ⅔ to about 3/2 of the third pitch.
